(19) United States
(12) Patent Application Publication
(10) Pub. No.: US 2025/0372383 A1
(43) Pub. Date: Dec. 4, 2025

(54) SEMICONDUCTOR STRUCTURE AND MANUFACTURING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/889,925

(22) Filed: Sep. 19, 2024

(30) Foreign Application Priority Data
Jun. 4, 2024 (CN) 202410718207.6

(51) Int. Cl. H01L 21/225; H01L 29/20; H01L 29/66; H01L 29/872

(52) U.S. Cl. CPC H01L 21/2258; H10D 8/051; H10D 8/60; H10D 62/8503

(57) ABSTRACT

Disclosed are a semiconductor structure and a manufacturing method thereof. The manufacturing method includes: sequentially stacking a substrate, a GaN drift layer and a protective layer; etching the protective layer to form an opening penetrating through the protective layer; forming a metal layer at least located in the opening; and forming a P-type region by performing high-temperature annealing to diffuse metal ions from the metal layer into the GaN drift layer under the opening. According to the present disclosure, the P-type region is formed by the Mg diffusion. The diffused Mg may better replace the Ga vacancy, in the GaN, so that most of the incorporated Mg atoms are located at the Ga vacancy, and thus the proportion of Mg atoms in the Ga vacancy is increased, the probability of binding with an H-bond is reduced, and the activation efficiency of the Mg is increased.

### CROSS-REFERENCE TO RELATED APPLICATIONS

The present disclosure claims priority to Chinese Patent Application No. 202410718207.6, filed on Jun. 4, 2024, all contents of which are incorporated herein in its entirety by reference.

### TECHNICAL FIELD

The present disclosure relates to the field of semiconductor technologies, and in particular, to a semiconductor structure and a manufacturing method thereof.

### BACKGROUND

Junction Barrier Schottky diodes (JBS) have become a research hotspot for an enhancement mode Schottky diode. The outstanding advantages of JBS diodes are that they have the on-state and fast switching characteristics of Schottky barrier diodes, and the off-state and low leakage current characteristics of Positive Intrinsic-Negative (PIN) diodes. The GaN stands out in the fabrication of high-performance power devices due to a larger bandgap, a higher critical breakdown field, and a higher electron saturation drift velocity, as well as excellent physical and chemical properties for GaN such as a chemical stability, a high-temperature resistance and a radiation resistance. The GaN has great application potential.

A P-type region in the JBS is usually realized by ion implantation. Firstly, the ion implantation process requires a very high ion implantation energy, and a very high requirement is provided for an implantation apparatus; secondly, the high ion implantation device is easy to causes great damage to the lattice of the implanted material; in addition, the diffusion phenomenon of implanted ions results in an inaccurate channel width, and an unreliable PN junction is easily broken down, thereby causing leakage current.

### SUMMARY

In view of this, embodiments of the present disclosure provide a semiconductor structure and a manufacturing method thereof to solve the problem of low quality of a P-type region of a JBS device.

According to one aspect of the present disclosure, an embodiment of the present disclosure provides a manufacturing method of a semiconductor structure, including: sequentially stacking a substrate, a GaN drift layer, and a protective layer; etching the protective layer to form an opening penetrating through the protective layer; forming a metal layer at least located in the opening; and forming a P-type region by performing high-temperature annealing to diffuse metal ions from the metal layer into the GaN drift layer under the opening.

As an optional embodiment, the metal layer is a Mg metal layer or a Mg/Al/Ti stacked metal layer.

As an optional embodiment, the metal ions include Mg ions.

As an optional embodiment, the opening penetrates through the protective layer and partially penetrates through the GaN drift layer.

As an optional embodiment, a sidewall of the P-type region is arc-shaped.

As an optional embodiment, the manufacturing method further includes: after removing the metal layer, performing a secondary epitaxy of a P-type material layer in the opening.

As an optional embodiment, a thickness of the P-type material layer is greater than or equal to a depth of a part of the opening located in the GaN drift layer and less than or equal to a total depth of the opening.

As an optional embodiment, the manufacturing method further includes: disposing an anode on a side of the P-type material layer and the protective layer away from the substrate, and disposing a cathode on a side of the substrate away from the GaN drift layer.

As an optional embodiment, an insertion layer is further disposed between the GaN drift layer and the protective layer, and a material of the insertion layer includes at least one of AlGaN or AlN.

According to another aspect of the present disclosure, an embodiment of the present disclosure provides a semiconductor structure, including: a substrate, a GaN drift layer, and a protective layer sequentially stacked. The protective layer includes an opening penetrating through the protective layer, and a metal layer is at least located in the opening; and a P-type region located in the GaN drift layer under the opening.

As an optional embodiment, the P-type region is formed by performing high-temperature annealing to diffuse metal ions from the metal layer into the GaN drift layer under the opening.

As an optional embodiment, the opening penetrates through the protective layer and partially penetrates through the GaN drift layer.

As an optional embodiment, a sidewall of the P-type region is arc-shaped.

As an optional embodiment, the semiconductor structure further includes: a P-type material layer, located in the opening and on a side of the P-type region away from the substrate.

As an optional embodiment, a thickness of the P-type material layer is greater than or equal to a depth of a part of the opening located in the GaN drift layer and less than or equal to a total depth of the opening.

As an optional embodiment, a material of the protective layer includes at least one of AlGaN or AlN.

As an optional embodiment, when the material of the protective layer is AlGaN, a content of Al in the protective layer varies along a direction from the substrate to the protective layer, the variation manner includes at least one of a periodic variation, an increasing variation, or a decreasing variation.

As an optional embodiment, an insertion layer is further disposed between the GaN drift layer and the protective layer, and a material of the insertion layer includes at least one of AlGaN or AlN.

As an optional embodiment, the material of the insertion layer is different from a material of the protective layer.

As an optional embodiment, a metal layer is a Mg metal layer or a Mg/Al/Ti stacked metal layer.

### BRIEF DESCRIPTION OF THE DRAWINGS

FIG. 1 is a schematic flowchart of a manufacturing method of a semiconductor structure according to an embodiment of the present disclosure.

FIG. 2 to FIG. 5 are intermediate structural diagrams of a semiconductor structure in a manufacturing process according to an embodiment of the present disclosure.

FIG. 6 is a schematic structural diagram of a semiconductor structure according to an embodiment of the present disclosure.

FIG. 7 and FIG. 8 are intermediate structural diagrams of a semiconductor structure in a manufacturing process according to an embodiment of the present disclosure.

FIG. 9 to FIG. 14 are intermediate structural diagrams of a semiconductor structure in a manufacturing process according to an embodiment of the present disclosure.

FIG. 15a and FIG. 15b are schematic structural diagram of a semiconductor structure according to an embodiment of the present disclosure.

### DETAILED DESCRIPTION OF THE EMBODIMENTS

Technical solutions in the embodiments of the present disclosure will be clearly described below with reference to the accompanying drawings in the embodiments of the present disclosure. Apparently, the described embodiments are a part of the embodiments of the present disclosure, rather than all the embodiments. Based on the embodiments of the present disclosure, all other embodiments obtained by those of ordinary skill in the art without making creative labor are within the protection scope of the present disclosure.

In order to solve the problem of low quality of a P-type region of a JBS device, the present disclosure provides a semiconductor structure and a manufacturing method thereof. The manufacturing method includes: sequentially stacking a substrate, a GaN drift layer, and a protective layer; etching the protective layer to form an opening penetrating through the protective layer; forming a metal layer at least located in the opening; and forming a P-type region by performing high-temperature annealing to diffuse metal ions from the metal layer into the GaN drift layer under the opening. According to the present disclosure, the P-type region is formed by an Mg diffusion method. On one hand, the diffused Mg may better replace the Ga vacancy, in the GaN, so that most of the incorporated Mg atoms are located at the Ga vacancy, and thus the proportion of Mg atoms in the Ga vacancy is increased, the probability of binding with an H-bond is reduced, and the activation efficiency of the Mg is increased, and on the other hand, issues such as lattice damage caused by the ion implantation method to form the P-type region are avoided, thereby improving the quality of the P-type region.

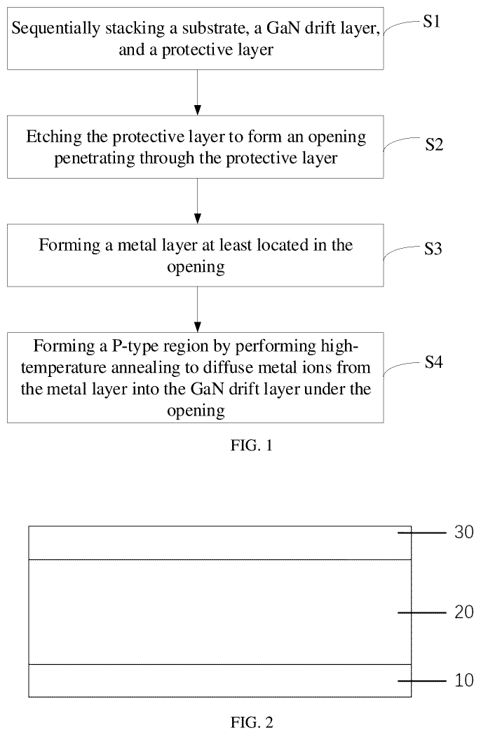

The semiconductor structure and a manufacturing method thereof mentioned in the present disclosure are further illustrated below with reference to FIG. 1 to FIG. 15b.

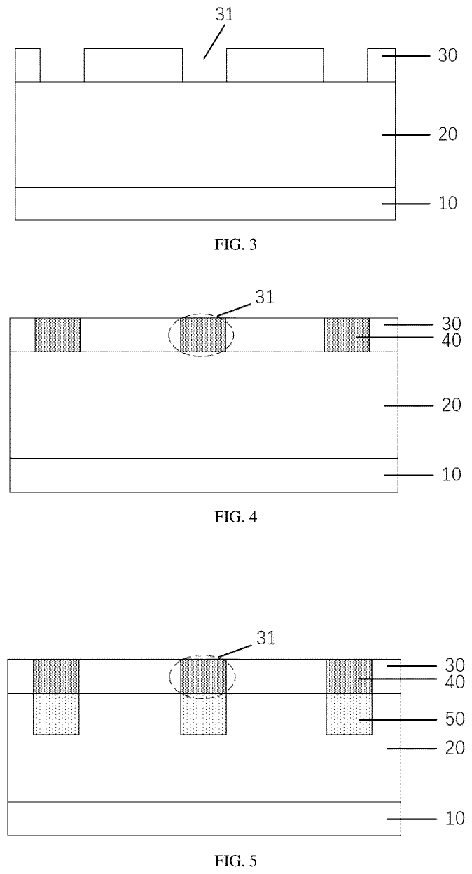

According to one aspect of the present disclosure, an embodiment of the present disclosure provides a manufacturing method of a semiconductor structure. FIG. 1 is a schematic flowchart of a manufacturing method of a semiconductor structure according to an embodiment of the present disclosure. FIG. 2 to FIG. 5 are intermediate structural diagrams of a semiconductor structure in a manufacturing process according to an embodiment of the present disclosure. As shown in FIG. 1, the manufacturing method of a semiconductor structure provided in an embodiment of the present disclosure includes the following steps:

Step S1: sequentially stacking a substrate, a GaN drift layer, and a protective layer.

Specifically, as shown in FIG. 2, the substrate 10, the GaN drift layer 20, and the protective layer 30 are stacked sequentially. The material of the substrate 10 includes Si, SiC, GaN or diamond. The GaN drift layer 20 is n-type doped, and the n-type ion doping concentration is less than 1×10¹⁷ cm⁻³. The material of the protective layer 30 includes at least one of AlGaN or AlN.

Step S2: etching the protective layer to form an opening penetrating through the protective layer.

Specifically, as shown in FIG. 3, the protective layer 30 is etched to form the opening(s) 31 that penetrates through the protective layer 30.

Step S3: forming a metal layer at least located in the opening.

Specifically, as shown in FIG. 4, the metal layer 40 is formed at least in opening(s) 31. The metal layer 40 is a Mg metal layer or a Mg/Al/Ti stacked metal layer. The metal layer 40 may be formed by thermal evaporation, electron beam evaporation or sputtering.

Step S4: forming a P-type region by performing high-temperature annealing to diffuse metal ions from the metal layer into the GaN drift layer under the opening.

Specifically, as shown in FIG. 5, the metal ions from the metal layer 40 are diffused into the GaN drift layer 20 under the opening(s) 31 by high-temperature annealing to form the P-type region 50. The metal ions include Mg ions. The arrangement of the protective layer 30 may act as a diffusion barrier to prevent the metal ions from diffusing into the GaN drift layer 20 under the non-opening(s) 31, so that the P-type region 50 is distributed at intervals.

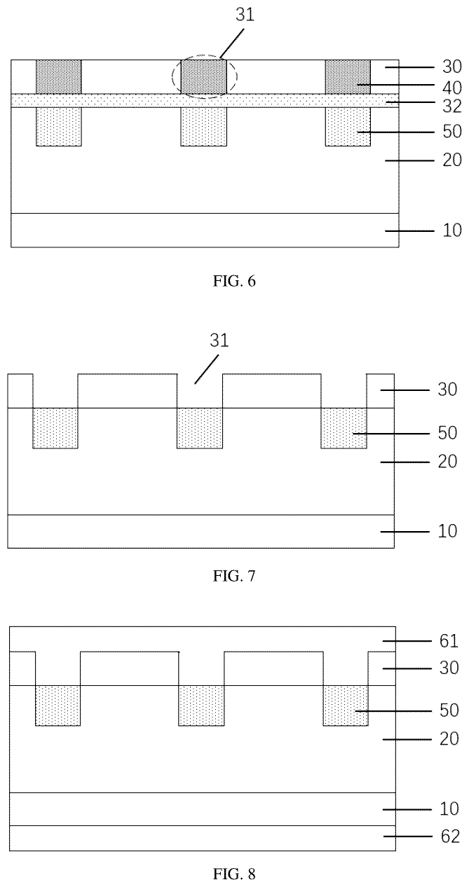

In an embodiment, FIG. 6 is a schematic structural diagram of a semiconductor structure according to an embodiment of the present disclosure. As shown in FIG. 6, the insertion layer 32 is further disposed between the GaN drift layer 20 and the protective layer 30, and the material of the insertion layer 32 includes at least one of AlGaN or AlN. The material of the insertion layer 32 is different from the material of the protective layer 30. The insertion layer 32 and the protective layer 30 have an etch selectivity. When the opening(s) 31 of the protective layer 30 is etched, the insertion layer 32 may function as an etch stop. In addition, the thickness of the insertion layer 32 is less than the thickness of the protective layer 30, and the insertion layer 32 may play a role in improving the uniformity of the diffused metal ions.

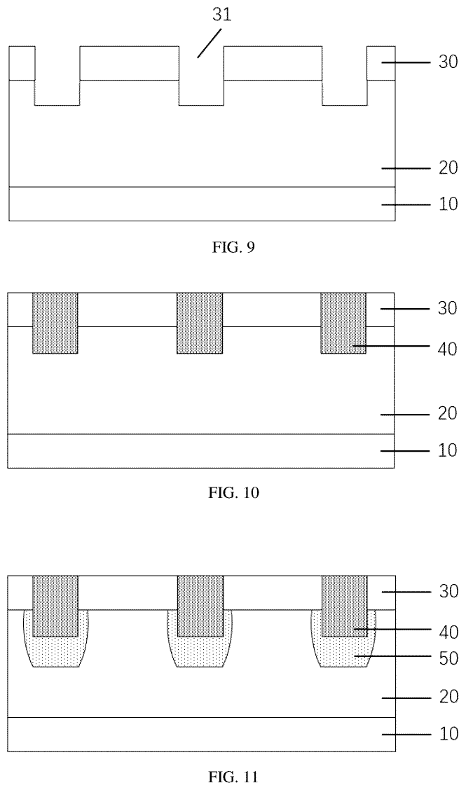

In an embodiment, the manufacturing method of a semiconductor structure further includes: after removing the metal layer, disposing an anode on a side of the P-type material and the protective layer away from the substrate, and disposing a cathode on a side of the substrate away from the GaN drift layer. FIG. 7 and FIG. 8 are intermediate structural diagrams of a semiconductor structure in a manufacturing process according to an embodiment of the present disclosure. Specifically, as shown in FIG. 7, the metal layer 40 is removed. As shown in FIG. 8, the anode 61 is disposed on the side of the P-type material layer 50 and the protective layer 30 away from the substrate 10, and the cathode 62 is disposed on the side of the substrate 10 away from the GaN drift layer 20, thereby forming a JBS structure as shown in FIG. 8. A surface of the anode 61 close to a side of the substrate 10 is non-planar, and the anode 61 is comb-shaped for filling the opening(s) 31 and the entire surface of the anode 61 covers the protective layer 30, which may better control the P-type regions 50 and a conductive channel between each the P-type regions 50. According to the present disclosure, the P-type region 50 in the JBS structure is formed by the Mg diffusion method. On one hand, the diffused Mg may better replace the Ga vacancy in the GaN, so that most of the incorporated Mg atoms are located at the Ga vacancy, and thus the proportion of the Mg atoms in the Ga vacancy is increased, the probability of binding with an H-bond is reduced, and the activation efficiency of the Mg is increased. On the other hand, issues such as lattice damage caused by the ion implantation method to form the P-type region 50 are avoided, thereby improving the quality of the P-type region 50. A material of the protective layer 30 in the embodiment includes AlGaN or AlN, which may be retained in the semiconductor structure, thereby simplifying the procedure and saving costs.

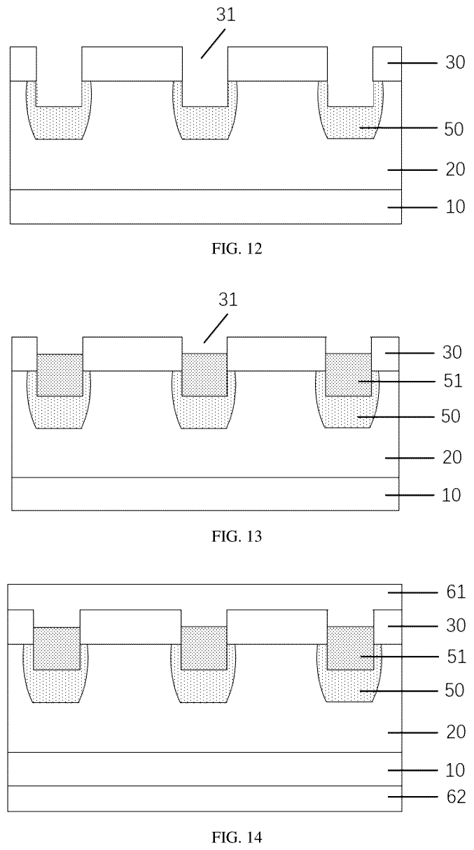

In an embodiment, FIG. 9 to FIG. 14 are intermediate structural diagrams of a semiconductor structure in a manufacturing process according to an embodiment of the present disclosure. As shown in FIG. 9, the opening(s) 31 in the step S2 penetrates through the protective layer 30 and partially penetrates through the GaN drift layer 20. As shown in FIG. 10, a thickness of the metal layer 40 in the step S3 is greater than or equal to a depth of a part of the opening(s) 31. As shown in FIG. 11, in the step S4, the metal ions in the metal layer 40 are diffused into the GaN drift layer 20 under the opening(s) 31 for high-temperature annealing to form the P-type region 50. The P-type region 50 formed by diffusion is not only located under the opening(s) 31, but also on the side of the opening(s) 31, and a sidewall of the P-type region 50 is arc-shaped. As shown in FIG. 12, the metal layer 40 is removed. As shown in FIG. 13, the P-type material layer 51 is secondary epitaxial in the opening(s) 31, a thickness of the P-type material layer 51 is greater than or equal to a depth of the opening(s) 31 located in the GaN drift layer 20 and less than or equal to a total depth of the opening(s) 31. As shown in FIG. 14, the anode 61 is disposed on the side of the P-type material layer 51 and the protective layer 30 away from the substrate 10, and the cathode 62 is disposed on the side of the substrate 10 away from the GaN drift layer 20. When a thickness of the P-type material layer 51 is less than the total depth of the opening(s) 31, the surface of the anode 61 close to a side of the substrate 10 is non-planar, the anode 61 is a comb-shaped filling the opening(s) 31 and the entire surface of the anode 61 covers the protective layer 30, which may better control a conductive channel of the P-type region 50 and a conductive channel of between each the P-type region 50. In the embodiment, the P-type material layer 51 is formed by the secondary epitaxy, which may further expand a range of the P-type region and improve a withstand voltage performance of the device. At the same time, the P-type material layer 51 grows on the P-type region 50 and has good quality, which may ensure the quality of the P-type region.

According to another aspect of the present disclosure, an embodiment of the present disclosure provides a semiconductor structure, which includes the semiconductor structure obtained by the manufacturing method of a semiconductor structure. As shown in FIG. 5, the semiconductor structure includes a substrate 10, a GaN drift layer 20 and a protective layer 30 sequentially stacked. The protective layer 30 includes an opening(s) 31 penetrating through the protective layer 30, and a metal layer 40 is at least located in the opening(s) 31; and a P-type region 50 located in the GaN drift layer 20 under the opening(s) 31. the P-type region 50 is formed by high-temperature annealing to diffuse metal ions from the metal layer 40 into the GaN drift layer 20 under the opening(s) 31. the metal layer 40 is a Mg metal layer or a Mg/Al/Ti stacked metal layer. The material of the protective layer 30 includes at least one of AlGaN or AlN. When the material of the protective layer 30 is AlGaN, a content of an Al in the protective layer 30 varies along a direction from the substrate 10 to the protective layer 30, and the variation manner includes at least one of a periodic varies, an increasing varies, or a decreasing varies. The component variation of the protective layer 30 facilitates accurate control of the etching depth of the opening(s) 31.

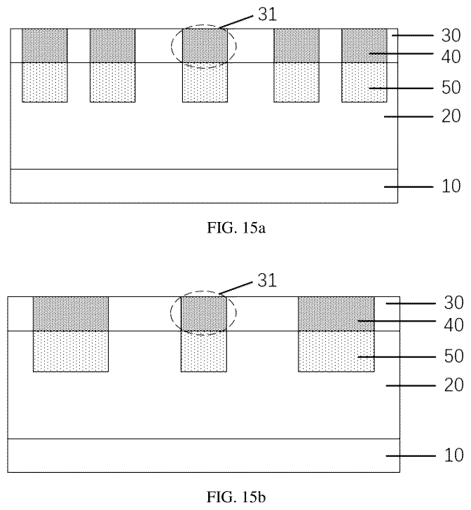

In an embodiment, FIG. 15a and FIG. 15b are schematic structural diagram of a semiconductor structure according to an embodiment of the present disclosure. The P-type region 50 is an elongated structure arranged at intervals. Optionally, the spacing distances of the plurality of the elongated structures arranged at intervals are gradually decreased from the middle to the two sides (as shown in FIG. 15a), and the widths of the plurality of the elongated structures arranged at intervals are gradually increased from the middle to the two sides (as shown in FIG. 15b). The interval distance and width of the elongated structures may be implemented by controlling the interval distance and width of the opening(s) 31. By controlling the interval distance or width of the P-type region 50, the electric field distribution of the high electric field intensity region of the semiconductor structure may be adjusted, thereby suppressing the breakdown of the semiconductor structure at an edge of the electrode under a high voltage.

In an embodiment, as shown in FIG. 6, an insertion layer 32 is further included between the GaN drift layer 20 and the protective layer 30. A material of the insertion layer 32 includes at least one of AlGaN or AlN, and the material of the insertion layer 32 is different from a material of the protective layer 30. The insertion layer 32 and the protective layer 30 have an etching selectivity ratio. When the opening(s) 31 of the protective layer 30 is etched, the insertion layer 32 may act as an etching stop. In addition, a thickness of the insertion layer 32 is less than a thickness of the protective layer 30, and the insertion layer 32 may act to improve the uniformity of the diffused metal ions.

In an embodiment, the metal layer 40 is removed, as shown in FIG. 8, the semiconductor structure includes an anode 61 on a side of the P-type region 50 and the protective layer 30 away from the substrate 10, and a cathode 62 on a side of the substrate 10 away from the GaN drift layer 20, thereby forming a JBS structure as shown in FIG. 8.

In an embodiment, as shown in FIG. 12, the opening(s) 31 penetrates through the protective layer 30 and partially penetrates through the GaN drift layer 20, and the P-type region 50 is located in the GaN drift layer 20 under the opening(s) 31, and a sidewall of the P-type region 50 is arc-shaped. As shown in FIG. 14, the semiconductor structure further includes: a P-type material layer 51, located in the opening(s) 31 and on a side of the P-type region 50 away from the substrate 10. A thickness of the P-type material layer 51 is greater than or equal to a depth of a part of the opening(s) 31 located in the GaN drift layer 20 and less than or equal to a total depth of the opening(s) 31. The semiconductor structure includes an anode 61 on a side of the P-type material layer 51 and the protective layer 30 away from the substrate 10, and a cathode 62 on the side of the substrate 10 away from the GaN drift layer 20, thereby forming the JBS structure as shown in FIG. 14.

The present disclosure provides a semiconductor structure and a manufacturing method thereof. The manufacturing method of the semiconductor structure includes: sequentially stacking a substrate, a GaN drift layer and a protective layer; etching the protective layer to form an opening(s) penetrating through the protective layer; forming a metal layer at least located in the opening(s); and forming a P-type region by performing high-temperature annealing to diffuse metal ions from the metal layer into the GaN drift layer under the opening(s). According to the present disclosure, the P-type region is formed by the Mg diffusion method. On one hand, the diffused Mg may better replace the Ga vacancy in the GaN, so that most of the incorporated Mg atoms are located at the Ga vacancy, and thus the proportion of Mg atoms in the Ga vacancy is increased, the proportion of Mg atoms in the Ga vacancy is increased, the probability of binding with an H-bond is reduced, and the activation efficiency of the Mg is increased. On the other hand, issues such as lattice damage caused by the ion implantation method to form the P-type region are avoided, thereby improving the quality of the P-type region.

It should be understood that the terms “include” and variations thereof used in the present disclosure are open ended, that is, “including, but not limited to”. The term “one embodiment” means “at least one embodiment”; the term “another embodiment” means “at least one other embodiment”. In this specification, the illustrative statements of the above terms are not necessarily directed to the same embodiment or example. Moreover, the specific features, structures, materials or characteristics described may be combined in any suitable manner in any one or more embodiments or examples. In addition, in the case of no contradiction, a person skilled in the art may combine and bond different embodiments or examples and features from different embodiments or examples described in the present disclosure.

The foregoing description merely represents the best embodiments of the present disclosure and is not intended to limit the scope of the present disclosure. Any modifications, equivalent replacements, etc., made within the spirit and principles of the present disclosure are all within the protection scope of the present disclosure.

What is claimed is:

1. A manufacturing method of a semiconductor structure, comprising:
sequentially stacking a substrate, a GaN drift layer, and a protective layer;
etching the protective layer to form an opening penetrating through the protective layer;
forming a metal layer at least located in the opening; and
forming a P-type region by performing high-temperature annealing to diffuse metal ions from the metal layer into the GaN drift layer under the opening.

2. The manufacturing method of the semiconductor structure according to claim 1, wherein the metal layer is a Mg metal layer or a Mg/Al/Ti stacked metal layer.

3. The manufacturing method of the semiconductor structure according to claim 2, wherein the metal ions comprise Mg ions.

4. The manufacturing method of the semiconductor structure according to claim 1, wherein the opening penetrates through the protective layer and partially penetrates through the GaN drift layer.

5. The manufacturing method of the semiconductor structure according to claim 4, wherein a sidewall of the P-type region is arc-shaped.

6. The manufacturing method of the semiconductor structure according to claim 4, further comprising: after removing the metal layer, performing a secondary epitaxy of a P-type material layer in the opening.

7. The manufacturing method of the semiconductor structure according to claim 6, wherein a thickness of the P-type material layer is greater than or equal to a depth of a part of the opening in the GaN drift layer and less than or equal to a total depth of the opening.

8. The manufacturing method of the semiconductor structure according to claim 6, further comprising: disposing an anode on a side of the P-type material layer and the protective layer away from the substrate, and disposing a cathode on a side of the substrate away from the GaN drift layer.

9. The manufacturing method of the semiconductor structure according to claim 1, wherein an insertion layer is further disposed between the GaN drift layer and the protective layer, and a material of the insertion layer comprises at least one of AlGaN or AlN.

10. A semiconductor structure, comprising:
a substrate, a GaN drift layer, and a protective layer sequentially stacked, wherein the protective layer comprises an opening penetrating through the protective layer, and a metal layer is at least located in the opening; and
a P-type region located in the GaN drift layer under the opening.

11. The semiconductor structure according to claim 10, wherein the P-type region is formed by performing high-temperature annealing to diffuse metal ions from the metal layer into the GaN drift layer under the opening.

12. The semiconductor structure according to claim 10, wherein the opening penetrates through the protective layer and partially penetrates through the GaN drift layer.

13. The semiconductor structure according to claim 12, wherein a sidewall of the P-type region is arc-shaped.

14. The semiconductor structure according to claim 12, further comprising: a P-type material layer, located in the opening and on a side of the P-type region away from the substrate.

15. The semiconductor structure according to claim 14, wherein a thickness of the P-type material layer is greater than or equal to a depth of a part of the opening located in the GaN drift layer and less than or equal to a total depth of the opening.

16. The semiconductor structure according to claim 10, wherein a material of the protective layer comprises at least one of AlGaN or AlN.

17. The semiconductor structure according to claim 16, wherein the material of the protective layer is AlGaN, a content of an Al in the protective layer varies along a direction from the substrate to the protective layer, and the variation manner comprises at least one of a periodic variation, an increasing variation, or a decreasing variation.

18. The semiconductor structure according to claim 10, wherein an insertion layer is further disposed between the GaN drift layer and the protective layer, and a material of the insertion layer comprises at least one of AlGaN or AlN.

19. The semiconductor structure according to claim 18, wherein the material of the insertion layer is different from a material of the protective layer.

20. The semiconductor structure according to claim 10, wherein the metal layer is a Mg metal layer or a Mg/Al/Ti stacked metal layer.
